(19) United States
(12) Patent Application Publication
(10) Pub. No.: US 2025/0022827 A1
(43) Pub. Date: Jan. 16, 2025

(54) Preparation Method of Chip Package Structure and Package Structure

(71) Applicant: Guangdong Fozhixin Microelectronics Technology Research Co., Ltd, Foshan (CN)

(72) Inventors: Xiangang Hua, Foshan (CN); Shumin He, Foshan (CN); Bin Yang, Foshan (CN)

(21) Appl. No.: 18/749,681

(22) Filed: Jun. 21, 2024

Related U.S. Application Data
(63) Continuation of application No. PCT/CN2023/142260, filed on Dec. 27, 2023.

(30) Foreign Application Priority Data
Jul. 10, 2023 (CN) 202310838622.0
Jul. 10, 2023 (CN) 202310838628.8

(51) Int. Cl. H01L 23/00; H01L 21/56; H01L 21/78; H01L 25/00

(52) U.S. Cl. CPC H01L 24/19; H01L 21/78; H01L 24/82; H01L 24/97; H01L 25/50; H01L 21/568; H01L 2224/82947; H01L 2224/97

(57) ABSTRACT

The present disclosure relates to the technical field of semiconductors, and particularly discloses a preparation method of a chip package structure and a package structure. The preparation method of a chip package structure includes the following steps: providing a wafer and producing conductive structures on the wafer based on chip distribution; performing wafer dicing based on the chip distribution to obtain chip monomers; producing plastic package bodies including a plurality of chip monomers based on the chip monomers; and producing electric connection structures on the plastic package bodies. The preparation method of a chip package structure omits the processes of laser drilling and later metal layer covering, eliminates a deviation caused by laser drilling, and improves the processing precision of the package structure, thereby improving the yield of products, simplifying the whole chip packaging process, and effectively improving the packaging efficiency.

### CROSS REFERENCE TO RELATED APPLICATIONS

The present application is a Continuation Application of PCT Application No. PCT/CN2023/142260 filed on Dec. 27, 2023, which claims the benefit of Chinese Patent Application Nos. 202310838622.0 and 202310838628.8 filed on Jul. 10, 2023. All the above are hereby incorporated by reference in their entirety.

### TECHNICAL FIELD

This application relates to the technical field of semiconductors, and particularly relates to a preparation method of a chip package structure and a package structure.

### BACKGROUND

When a fan out package structure is packaged, laser drilling is required to be performed towards the front sides of plastic package bodies after plastic package layers are formed and metal layers are required to be filled to lead out PADs of chips. However, the operation of mounting and fixing the chips onto a carrier before the metal layers are filled has a certain deviation. A plastic packaging process of the chips may also cause chip position shift. Moreover, laser drilling is performed based on the position of the carrier as a reference object, and also has a certain deviation. Under the influence of various deviation data mentioned above, the laser drilling position is prone to deviate from the positions of the PADs of chips, resulting in inability of the metal layers to smoothly lead out the PADs, resulting in insufficient processing precision, and affecting the yield of products.

Currently, no effective technical solution has been proposed to solve the above problems.

### SUMMARY

The objective of this application is to provide a preparation method of a chip package structure and a package structure, to improve the processing precision of the package structure and increase the yield of products.

In a first aspect, this application provides a preparation method of a chip package structure, the method includes the following steps:
S1, providing a wafer and producing conductive structures on the wafer based on chip distribution;
S2, performing wafer dicing based on the chip distribution to obtain chip monomers;
S3, producing plastic package bodies including a plurality of chip monomers based on the chip monomers; and
S4, producing electric connection structures on the plastic package bodies.

Compared with a traditional packaging process, in the preparation method of a chip package structure of this application, first the chips on the wafer are used as processing benchmarks to produce the conductive structures, so that the conductive structures can be accurately arranged on the chips and protect the PADs of the chips; and plastic packaging is performed on the chip monomers obtained by dicing and the corresponding conductive structures simultaneously to obtain the plastic package bodies. Therefore, the preparation method of a chip package structure of this application omits the processes of laser drilling and later metal layer covering, eliminates a deviation caused by laser drilling, and improves the processing precision of the package structure, thereby improving the yield of products, simplifying the whole chip packaging process, and effectively improving the packaging efficiency.

In the preparation method of a chip package structure, the conductive structures are first balls;
step S1 includes:
S11, providing a wafer and mounting first balls on the wafer based on the chip distribution; and
step S3 includes:
S31, providing a carrier and fixing the chip monomers onto the carrier;
S32, performing plastic packaging on the first balls to form plastic package layers, the top surfaces of the plastic package layers being higher than or equal to the top ends of the first balls; and
S33, thinning the plastic package layers to make the tops of the first balls have flat exposed ends.

The preparation method of this application directly starts the first step of a packaging process on the wafer, the first balls directly connected to the PADs of chips are arranged on the surface of the wafer by step S1, that is, the corresponding first balls are directly arranged for the chips in different positions using the chips on the wafer as reference benchmarks, so that the accuracy of the positions where the first balls are produced is ensured.

In the preparation method of a chip package structure, the thinning process is performed to reduce ⅓ to ⅔ of the volume or height of the first balls.

In the preparation method of a chip package structure, the first balls cover PADs of chips on the wafer.

In the preparation method of a chip package structure, step S4 includes:
S41, producing rewiring layers, opening ink windows and mounting second balls sequentially on the tops of the plastic package layers to produce the electric connection structures; and
S42, releasing the carrier to obtain a plastic package body.

In the preparation method of a chip package structure, in step S31, the bottom surfaces of the chip monomers are fixed onto the top surface of the carrier based on temporary bonding layers.

The preparation method of a chip package structure further includes the following step:
S5, cutting the plastic package body after the electric connection structures are produced to obtain a finished package body.

The preparation method of a chip package structure further includes the following step performed between step S3 and step S4:
covering the flat exposed ends of the first balls with nickel metal layers.

In the preparation method of a chip package structure, the conductive structures are structural metal layers;
step S1 includes:
S11′, providing a wafer and arranging structural metal layers on the upper surface of the wafer based on the chip distribution; and
step S3 includes:
S31′, providing a carrier and fixing the chip monomers face down on the carrier based on temporary bonding layers; and
S32′, performing plastic packaging on the top surface of the carrier to make the top surfaces of plastic package layers higher than or equal to the back sides of the chip monomers to obtain plastic package bodies.

Compared with a traditional face-down packaging process, in the preparation method of a chip package structure of this application, first the chips on the wafer are used as processing benchmarks to produce the structural metal layers, so that the structural metal layers can be accurately arranged on the chips and protect the PADs of the chips; and the chip monomers and the structural metal layers are simultaneously packaged after the chip monomers are placed face down. Therefore, the preparation method of a chip package structure of this application omits the processes of laser drilling and later metal layer covering in an existing preparation method of a face-down package structure, eliminates a deviation caused by laser drilling, and improves the processing precision of the package structure, thereby improving the yield of products. In addition, the omission of the processes of laser drilling and later metal layer covering can also effectively improve the production efficiency of the package structure.

In the preparation method of a chip package structure, the structural metal layers are under bump metallization (UBM) layers or immersion tin layers.

In the preparation method of a chip package structure, when the structural metal layers are the UBM layers, the step of arranging the structural metal layers includes:
S111, defining a passivation pattern on the upper surface of the wafer based on the chip distribution; and
S112, depositing the UBM layers on the upper surface of the wafer according to the passivation pattern.

In the preparation method of a chip package structure, the step of arranging the structural metal layers includes the following step performed before step S111:
S110, providing dielectric thickening layers surrounding the PADs on the upper surface of the wafer based on the chip distribution.

In the preparation method of a chip package structure, the dielectric thickening layers are polyimide (PI) protective layers with a plurality of enclosing pores to surround the respective PADs on the wafer.

In the preparation method of a chip package structure, the UBM layers include sinking metal structural bodies, the number of the sinking metal structural bodies is the same as that of the PADs on the wafer, and the sinking bottoms of the sinking metal structural bodies completely cover the corresponding PADs.

In the preparation method of a chip package structure, the sinking metal structural bodies sink inwards obliquely.

In the preparation method of a chip package structure, the structural metal layers cover the PADs of the respective chips on the wafer.

In the preparation method of a chip package structure, step S4 includes:
S41′, releasing the carrier from the plastic package bodies; and
S42′, inverting the plastic package bodies after the carrier is released, and producing rewiring layers, opening ink windows and mounting balls sequentially.

In a second aspect, this application further provides a package structure, the package structure is prepared by the preparation method of a chip package structure provided in the first aspect.

In a packaging process of the chip package structure of this application, first the chips on the wafer are used as processing benchmarks to produce the conductive structures, so that the conductive structures can be accurately arranged on the chips and protect the PADs of the chips; and plastic packaging is performed on the chip monomers obtained by dicing and the corresponding conductive structures simultaneously to obtain the plastic package bodies. Therefore, the preparation method of a chip package structure of this application omits the processes of laser drilling and later metal layer covering, eliminates a deviation caused by laser drilling, and improves the processing precision of the package structure, thereby improving the yield of products, simplifying the whole chip packaging process, and effectively improving the packaging efficiency.

Based on the above, this application provides the preparation method of a chip package structure and the package structure, in the preparation method of the package structure, first the chips on the wafer are used as processing benchmarks to produce the conductive structures, so that the conductive structures can be accurately arranged on the chips and protect the PADs of the chips, and plastic packaging is performed on the chip monomers obtained by dicing and the corresponding conductive structures simultaneously to obtain the plastic package bodies. Therefore, the preparation method of a chip package structure of this application omits the processes of laser drilling and later metal layer covering, eliminates a deviation caused by laser drilling, and improves the processing precision of the package structure, thereby improving the yield of products, simplifying the whole chip packaging process, and effectively improving the packaging efficiency.

### BRIEF DESCRIPTION OF FIGURES

FIG. 1 is a flowchart of a preparation method of a chip package structure provided by embodiments of this application;

FIG. 2 is a flowchart of a preparation method of a chip package structure by face-up packaging provided by the embodiments of this application;

FIG. 3 is a process flowchart of a preparation method of a chip package structure by face-up packaging provided by the embodiments of this application;

FIG. 4 is a flowchart of a preparation method of a chip package structure by face-down packaging provided by the embodiments of this application;

FIG. 5 is a process flowchart of a preparation method of a chip package structure by face-down packaging provided by the embodiments of this application;

FIG. 6 is a schematic structural diagram of a package structure prepared by the preparation method of a chip package structure by face-up packaging provided by the embodiments of this application;

FIG. 7 is a schematic structural diagram of a package structure prepared by the preparation method of a chip package structure by face-down packaging provided by the embodiments of this application; and

FIG. 8 is another schematic structural diagram of the package structure prepared by the preparation method of a chip package structure by face-down packaging provided by the embodiments of this application.

Reference numerals: la. First plastic package layers; 2a. First chip monomers; 3a. First balls; 4a. First rewiring layers; 5a. First ink layers; 6a. Second balls; lb. Second plastic package layers; 2b. Second chip monomers; 3b. Structural metal layers; 4b. Second rewiring layers; 5b. Second ink layers; 6b. Third balls; and 7. Dielectric thickening layers.

### DETAILED DESCRIPTION

The implementations of the present disclosure are described in detail below. Examples of the implementations are shown in the accompanying drawings, and reference numerals that are the same or similar always indicate the same or similar elements or elements with the same or similar functions. The implementations described below with reference to the accompanying drawings are exemplary, are merely intended to illustrate the present disclosure and cannot be construed as limiting the present disclosure.

In the description of the present disclosure, it should be understood that terms “center”, “longitudinal”, “transverse”, “length”, “width”, “thickness”, “upper”, “lower”, “front”, “back”, “left”, “right”, “vertical”, “horizontal”, “top”, “bottom”, “inside”, “outside”, “clockwise”, “counterclockwise”, and the like indicate orientation or position relationship based on the orientation or position relationship shown in the drawings, are merely used for the convenience of describing the disclosure and simplifying the description, do not indicate or imply that the device or element referred to must have a specific orientation or be constructed and operated in a specific orientation, and thus cannot be construed as a limiting the present disclosure. In addition, terms “first” and “second” are only intended for description, but cannot be construed as indicating or implying relative importance or implicitly indicating the number of the specified technical features. Therefore, the features limited by “first” and “second” may explicitly or implicitly include one or more of the said features. In the description of the present disclosure, “a plurality of” means two or more, unless otherwise explicitly defined.

In the description of the present disclosure, it should be noted that unless otherwise explicitly specified and defined, the understanding of terms “installed”, “linked” and “connected” should be generalized, for example, the terms may be fixed connected, detachably connected or integrally connected; the terms may be mechanically connected, electrically connected or communicating with each other; and the terms may be directly linked, indirectly linked through an intermediate, communication between the interiors of two elements or an interactive relation between two elements. Those of ordinary skill in the art could understand the specific meanings of the above terms in the present disclosure according to specific situations.

In the present disclosure, unless otherwise explicitly specified or defined, the first feature being “on” or “beneath” the second feature may include the first feature being in direct contact with the second feature or the first feature being in contact with the second feature through another feature rather than in direct contact with the second feature. Moreover, the first feature being “above”, “on top of”, and “on” the second feature includes the first feature being directly above and diagonally above the second feature, or simply indicates that the first feature is horizontally higher than the second feature. The first feature being “below”, “under”, and “beneath” the second feature includes the first feature being directly below and diagonally below the second feature, or simply indicates that the first feature is horizontally lower than the second feature.

The disclosure hereinafter provides a lot of different implementations or examples to implement the different structures of the present disclosure. In order to simplify the disclosure of the present disclosure, the parts and configurations of the specific examples are described hereinafter. Of course, they are only illustrative rather than intended to limit the present disclosure. In addition, the present disclosure may repeat reference numbers or reference letters in different examples, and such repetition is intended for simplification and clarification rather than indicates the relation between the various implementations and/or configurations discussed. In addition, although the present disclosure provides the examples of various specific processes and materials, those of ordinary skill in the art can realize the application of other processes and/or the use of other materials.

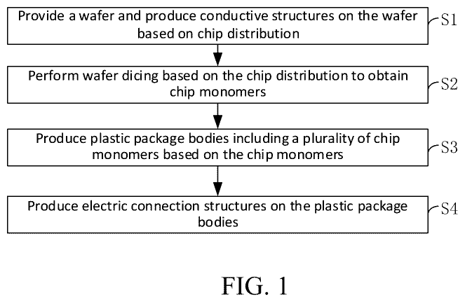

In a first aspect, referring to FIG. 1 to FIG. 5, some embodiments of this application provide a preparation method of a chip package structure, and the method includes the following steps:
S1, providing a wafer and producing conductive structures on the wafer based on chip distribution;
S2, performing wafer dicing based on the chip distribution to obtain chip monomers;
S3, producing plastic package bodies including a plurality of chip monomers based on the chip monomers; and
S4, producing electric connection structures on the plastic package bodies.

Specifically, the wafer refers to a silicon wafer used in production of a silicon semiconductor circuit, i.e., a plurality of chips may be prepared by wafer dicing. In fact, a wafer includes a plurality of tightly connected chips (i.e., die). These chips all have PADs or bumps for I/O connections, and a chip packaging process essentially involves designing a circuit to lead out the PADs of the chips used for the I/O connections.

More specifically, compared with the prior art, the preparation method in the embodiments of this application directly starts the first step of a packaging process on the wafer, the conductive structures are produced on the surface of the wafer by step S1, and the corresponding conductive structures are directly arranged for the chips in different positions using the chips on the wafer as reference benchmarks, so that the accuracy of the positions where the conductive structures are produced is ensured.

It should be noted that the PAD of each chip on the wafer is connected to the corresponding conductive structure, so that the conductive structure can be used as a contact point for electric connection of the chip, and the PAD of the corresponding chip can be connected to a subsequent electric connection structure based on the conductive structure and led out.

More specifically, the dicing process in step S2 is a wafer cutting process, which can cut the wafer into a plurality of chip monomers based on the distribution (preset distribution) characteristics of the chips on the wafer. Each chip monomer includes a die, a plurality of PADs, and conductive structures connected to the corresponding PADs respectively and produced in step S1.

More specifically, the packaging method in the embodiments of this application produces the conductive structures on the wafer before producing the chip monomers, so that the packaging method in the embodiments of this application omits a process of producing conductive structures on plastic package bodies to lead out PADs after laser drilling, and can produce electric connection structures on the conductive structures on the plastic package bodies. The process of producing the electric connection structures in step S4 is a process of producing relevant electric connection lines that may be prepared by a method for producing an electric connection structure used in an existing package structure, and the descriptions thereof are omitted herein.

Compared with a traditional packaging process, in the preparation method of a chip package structure in the embodiments of this application, first the chips on the wafer are used as processing benchmarks to produce the conductive structures, so that the conductive structures can be accurately arranged on the chips and protect the PADs of the chips, and plastic packaging is performed on the chip monomers obtained by dicing and the corresponding conductive structures simultaneously to obtain the plastic package bodies. Therefore, the preparation method of a chip package structure in the embodiments of this application omits the processes of laser drilling and later metal layer covering, eliminates a deviation caused by laser drilling, and improves the processing precision of the package structure, thereby improving the yield of products, simplifying the whole chip packaging process, and effectively improving the packaging efficiency.

A preparation process of a chip package structure generally includes two forms: face-up packaging and face-down packaging. Different packaging forms have different packaging processes. Corresponding to different packaging forms, the preparation method of a chip package structure in the embodiments of this application can configure appropriate conductive structures and plastic packaging processes.

In an existing face-up packaging process, first a plurality of chip monomers are fixed face up (with the PAD ends face up) onto a carrier, and plastic packaging is performed on the chip monomers to obtain plastic package bodies, the plastic package layers of the plastic package bodies are higher than the top surfaces of the chip monomers, i.e., completely covering the PADs of the chip monomers; laser drilling and metal layer deposition are performed on the plastic package bodies using the carrier as a benchmark, to lead out the PADs of the chip monomers in the plastic package bodies based on metal layers filled in the pores generated by laser drilling; and then, electric connection structures are produced on one side of the metal layers of the plastic package bodies to obtain an expected package structure. In the preparation process of the package structure, the operation of fixing the chip monomers onto the carrier has a certain positional deviation, the plastic packaging process may also cause the chip monomers to shift, and the laser drilling process also has a certain processing deviation. Under the combined effect of various deviation factors mentioned above, the pores generated by laser drilling in the package structure are prone to deviate from the PADs of the chip monomers, causing the metal layers to deviate from the PADs and be unable to lead out the PADs, and affecting the yield of products.

The preparation method of a chip package structure in the embodiments of this application is improved as follows for face-up packaging:

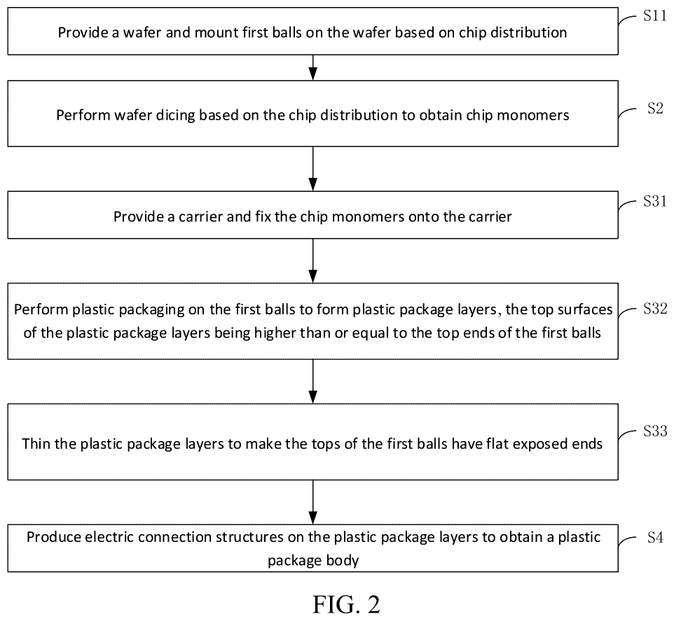

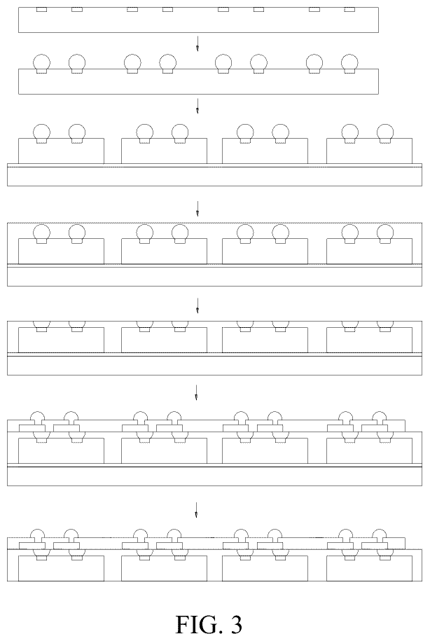

As shown in FIG. 2 and FIG. 3, in some preferred implementations, the conductive structures are first balls;
step S1 includes:
S11, providing a wafer and mounting first balls on the wafer based on the chip distribution; and
step S3 includes:
S31, providing a carrier and fixing the chip monomers onto the carrier;
S32, performing plastic packaging on the first balls to form plastic package layers, the top surfaces of the plastic package layers being higher than or equal to the top ends of the first balls; and
S33, thinning the plastic package layers to make the tops of the first balls have flat exposed ends.

The preparation method in the embodiments of this application directly starts the first step of a packaging process on the wafer, the first balls (typically mounted with tin solder) directly connected to the PADs of chips are arranged on the surface of the wafer by step S1, that is, the corresponding first balls are directly arranged for the chips in different positions using the chips on the wafer as reference benchmarks, so that the accuracy of the positions where the first balls are produced is ensured.

It should be noted that the PAD of each chip on the wafer is connected to the corresponding first ball, so that the first ball can be used as a contact point for electric connection of the chip, and the PAD of the corresponding chip can be connected to a subsequent electric connection structure based on the first ball and led out.

More specifically, the dicing process in step S2 is a wafer cutting process. Each chip monomer includes a die, a plurality of PADs, and first balls connected to the corresponding PADs respectively and produced in step S1.

More specifically, in the preparation method in the embodiments of this application, the chip monomers are fixed by face-up packaging, i.e., the ends of the chip monomers far from the PADs are fixed flat onto the top surface of the carrier. In step S31, a plurality of chip monomers are fixed onto the carrier to achieve mass production of packaged chips.

More specifically, the top ends of the first balls originally arranged on the chips are spherical surfaces, and are difficult to be used as PAD lead-out structures. Therefore, the method in the embodiments of this application combines steps S32 and S33 to flatten the tops of the first balls into flat exposed ends. The plastic packaging process in step S32 and the thinning process in step S33 are common means for providing plastic package layers with an appropriate thickness. In the method in the embodiments of this application, the first balls are arranged before taking the common means to achieve enclosed plastic packaging of the first balls and shape adjustment of the first balls, so that the first balls are used for leading out the PADs of the chips and as metal layers with the flat exposed ends. Compared with the prior art, in the preparation method in the embodiments of this application, ball mounting is additionally performed on the wafer, the processes of laser drilling and metal layer deposition are omitted, and structural adjustment of the first balls is achieved by the thinning process, so that the first balls can be directly used as lead-out metal of the PADs. Therefore, in the preparation method in the embodiments of this application, the electric connection structures can be produced on the first balls with the flat exposed ends directly by step S4 after the thinning process.

Compared with a traditional packaging process, in the preparation method of a chip package structure in the embodiments of this application, first the chips on the wafer are used as processing benchmarks to produce the first balls, so that the first balls can be accurately arranged on the chips and protect the PADs of the chips; the chip monomers and the first balls are simultaneously packaged after the chip monomers are fixed, to ensure that the first balls can be accurately connected and lead out the PADs; and then by the plastic packaging and thinning processes, the first balls can be used as the metal layers for connecting the PADs. Therefore, the preparation method of a chip package structure in the embodiments of this application omits the processes of laser drilling and later metal layer covering, eliminates a deviation caused by laser drilling, and improves the processing precision of the package structure, thereby improving the yield of products, simplifying the whole chip packaging process, and effectively improving the packaging efficiency.

In some preferred implementations, the thinning process is performed to reduce ⅓ to ⅔ of the volume or height of the first balls.

Specifically, the thinning process may be performed to reduce ⅓ to ⅔ of the volume of the first balls, or be performed to reduce ⅓ to ⅔ of the height of the first balls. In the embodiments of this application, considering that the volume of the first balls is difficult to determine, it is preferred to reduce ⅓ to ⅔ of the height of the first balls, so that after the thinning process, the top surfaces of the spherical first balls have the flat exposed ends with a sufficiently large area and being convenient for producing the electric connection structures for connection.

More specifically, in the embodiments of this application, the thinning process is performed to reduce ⅗ of the height of the first balls. The bottom of the balls generally sinks slightly on a contact object, so the centers of gravity of the balls are lower than the centers of the balls. The height where the cross-sectional area is the largest is slightly lower than the center height, so the thinning process of the preparation method of a chip package structure in the embodiments of this application is performed to reduce ⅗ of the height of the first balls, to maximize the area of the flat exposed ends of the first balls, and ensure that the first balls can smoothly lead out the PADs and facilitate subsequent production of the electric connection structures for connection and contact.

In some preferred implementations, the first balls cover the PADs of the chips on the wafer.

Specifically, the first balls completely cover the PADs, can effectively protect the PADs from corrosion and have good contact ends for lead-out. The maximum cross-sectional area of the first balls completely covering the PADs is generally larger than the area of the PADs. Therefore, the area of the flat exposed ends obtained by the thinning process is larger than the area of the PADs, which is conducive to connecting the electric connection structures.

In some preferred implementations, step S4 includes:
S41, producing rewiring layers, opening ink windows and mounting second balls sequentially on the tops of the plastic package layers to produce the electric connection structures; and
S42, releasing the carrier to obtain a plastic package body.

Specifically, the top surfaces of the plastic package bodies obtained by the thinning process in step S33 are provided with the first balls directly connected to the PADs, and the first balls have the flat exposed ends. Therefore, the preparation method of a chip package structure in the embodiments of this application can obtain the electric connection structures connected to the first balls and used for leading out the PADs directly by producing the rewiring layers, opening the ink windows and mounting the balls in step S41.

In some preferred implementations, in step S31, the bottom surfaces of the chip monomers are fixed onto the top surface of the carrier based on temporary bonding layers.

Specifically, since the chip monomers and the plastic package layers are connected to the carrier based on the temporary bonding layers, the carrier can be quickly released by releasing the temporary bonding layers in step S42.

In some preferred implementations, the method further includes the following step:
S5, cutting the plastic package body after the electric connection structures are produced to obtain a finished package body.

Specifically, a plurality of chip monomers can be fixed in step S31, so that the preparation method of a chip package structure in the embodiments of this application can simultaneously achieve preparation of a plurality of package structures, and achieve mass processing of the package structures by separating the package structure based on step S5 to obtain a plurality of finished package bodies.

In some preferred implementations, the method further includes the following step performed between step S3 and step S4:
covering the flat exposed ends of the first balls with nickel metal layers.

Specifically, the first balls are covered with the nickel metal layers to protect the flat exposed ends of the first balls, and prevent the first balls from being oxidized in the process of producing the electric connection structures and affecting the lead-out effect.

In addition, except face-up packaging, in a preparation process of an existing face-down package structure, first a plurality of chip monomers are required to be fixed face down onto a carrier and a plastic packaging process is required to be performed on the chip monomers to obtain plastic package bodies; then, the carrier is released from the plastic package bodies and a new carrier is arranged on the other side; then, laser drilling and metal layer deposition are performed on the plastic package bodies using the new carrier as a benchmark, to lead out the PADs of the chip monomers in the plastic package bodies based on metal layers filled in the pores generated by laser drilling; and then, electric connection structures are produced on one side of the metal layers of the plastic package bodies to obtain an expected package structure. In the preparation process of the package structure, the operation of inverting the chip monomers on the carrier has a certain positional deviation, the plastic packaging process may also cause the chip monomers to shift, the laser drilling process also has a certain processing deviation, and the new carrier is used as a reference for performing the drilling process. Under the combined effect of various deviation factors mentioned above, the pores in the package structure are prone to deviate from the PADs of the chip monomers, causing the metal layers to deviate from the PADs and be unable to lead out the PADs, and affecting the yield of products.

The preparation method of a chip package structure in the embodiments of this application is improved as follows for face-down packaging:

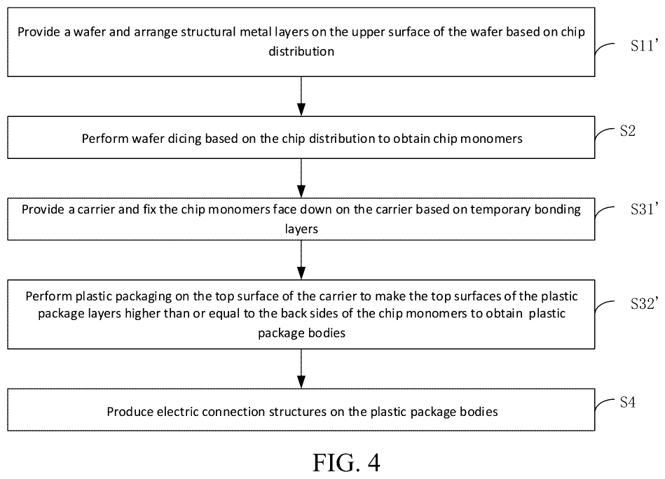

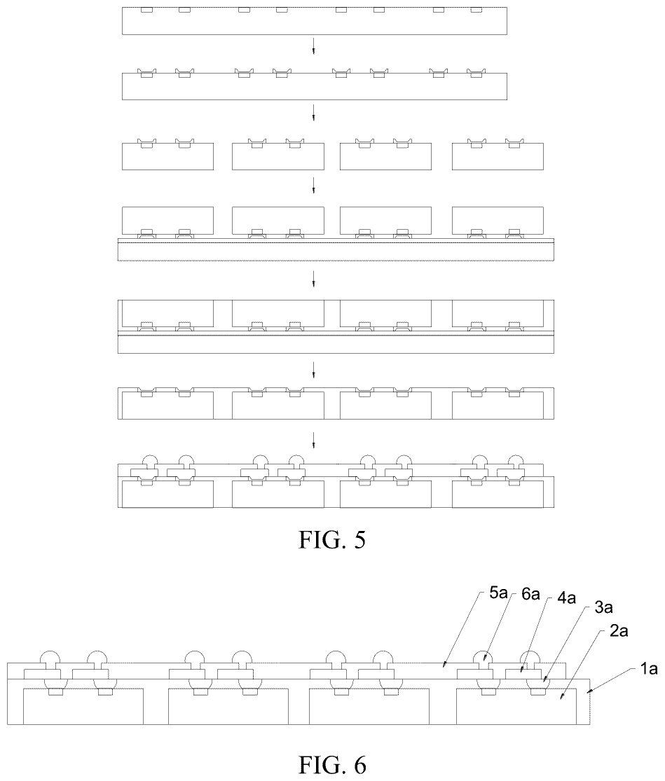

As shown in FIG. 4 and FIG. 5, in some preferred implementations, the conductive structures are structural metal layers;
step S1 includes:
S11′, providing a wafer and arranging structural metal layers on the upper surface of the wafer based on the chip distribution; and
step S3 includes:
S31′, providing a carrier and fixing the chip monomers face down on the carrier based on temporary bonding layers; and
S32′, performing plastic packaging on the top surface of the carrier to make the top surfaces of plastic package layers higher than or equal to the back sides of the chip monomers to obtain plastic package bodies.

More specifically, compared with the prior art, the preparation method of a chip package structure in the embodiments of this application directly starts the first step of a packaging process on the wafer, the structural metal layers are arranged on the surface of the wafer by step S1, i.e. the corresponding structural metal layers are directly arranged for the chips in different positions using the positions of the chips on the wafer as reference benchmarks, so that the accuracy of the positions where the structural metal layers are produced is ensured. It should be noted that the PAD of each chip on the wafer is connected to the corresponding structural metal layer, so that the structural metal layer can be used as a contact point for electric connection of the chip, and the PAD of the corresponding chip can be connected to a subsequent electric connection structure based on the structural metal layer and led out. The PADs of the chips are typically made of aluminum, or copper, or aluminum copper alloy, which is easily corroded by chemicals. Therefore, the structural metal layers can protect the PADs of the chips.

More specifically, the dicing process in step S2 is a wafer cutting process. Each chip monomer includes a die, a plurality of PADs, and structural metal layers produced in step S1.

More specifically, the ends of the chips with the PADs are front sides, and the ends of the chips far from the PADs are back sides. In step S31′, after the chip monomers are inverted, the front sides (the structural metal layers of the chip monomers) are fixed onto the carrier to make the back sides of the chip monomers face up. In step S31′, a plurality of chip monomers are fixed onto the carrier to achieve mass production of packaged chips.

More specifically, the plastic packaging process can fix the relative positions between a plurality of chip monomers, and facilitate subsequent use of one or more chips to produce relevant electric connection structures to obtain the expected packaged chips. In addition, since the chip monomers are fixed onto the carrier based on the structural metal layers, the plastic packaging process can generate groove-like structures surrounding the structural metal layers, thus forming deposited pores similar to those formed by laser drilling in the existing face-down package structure. Since the interior of the operation structure is already covered with the structural metal layers, the packaging method in the embodiments of this application can omit a metal layer deposition process performed on the plastic package bodies to lead out the PADs after laser drilling, and can produce the electric connection structures on the structural metal layers directly by step S4.

Compared with a traditional face-down packaging process, in the preparation method of a chip package structure in the embodiments of this application, first the chips on the wafer are used as processing benchmarks to produce the structural metal layers, so that the structural metal layers can be accurately arranged on the chips and protect the PADs of the chips; and the chip monomers and the structural metal layers are simultaneously packaged after the chip monomers are placed face down. Therefore, the preparation method of a chip package structure in the embodiments of this application omits the processes of laser drilling and later metal layer covering in an existing preparation method of a face-down package structure, eliminates a deviation caused by laser drilling, and improves the processing precision of the package structure, thereby improving the yield of products. In addition, the omission of the processes of laser drilling and later metal layer covering can also effectively improve the production efficiency of the package structure.

In some preferred implementations, the structural metal layers are under bump metallization (UBM) layers or immersion tin layers.

Specifically, the UBM layers, i.e., the under bump metallization layers, have the structural features of sinking grooves, can connect, protect and lead out the PADs of the chips, are formed by a deposition method, and may be implemented by sputtering, electroless, or plating.

More specifically, the immersion tin layers are formed through a tin immersion process, have the characteristics of smoothness, flatness and compactness, and can evenly cover the PADs of the chips to lead out the PADs.

In some preferred implementations, when the structural metal layers are the UBM layers, the step of arranging the structural metal layers includes:
S111, defining a passivation pattern on the upper surface of the wafer based on the chip distribution; and
S112, depositing the UBM layers on the upper surface of the wafer according to the passivation pattern.

Specifically, the passivation pattern is designed based on the chip distribution, so that the PAD of each chip on the whole wafer is correspondingly provided with the UBM layer.

In some preferred implementations, the step of arranging the structural metal layers includes the following step performed before step S111:
S110, providing dielectric thickening layers surrounding the PADs on the upper surface of the wafer based on the chip distribution.

Specifically, by arranging the dielectric thickening layers, the parts outside the PADs in the chips can be blocked to form protection for the chips, and openings are formed at the PADs, so that the UBM layers are deposited based on the dielectric thickening layers; the contraction of UBM layers is more compact and the UBM layers are mainly deposited in the openings, so that the electric connection structures can directly connect with the UBM layers deposited in the middle parts of the PADs, and the wiring range is shortened; and the distance between the chips in the whole plastic package body is smaller, the number of the chip monomers in the plastic package body in the packaging process each time is increased, and the production efficiency is improved.

More specifically, the dielectric thickening layers are made of a synthetic resin film, which is one of an Ajinomoto build-up film (ABF), a polyimide (PI) film, and an ABF like film.

In some preferred implementations, the dielectric thickening layers are PI protective layers with a plurality of enclosing pores to surround the respective PADs on the wafer.

In some preferred implementations, the structural metal layers cover the PADs of the respective chips on the wafer.

In some preferred implementations, the UBM layers include sinking metal structural bodies, the number of the sinking metal structural bodies is the same as that of the PADs on the wafer, and the sinking bottoms of the sinking metal structural bodies completely cover the corresponding PADs.

Specifically, in the embodiments of this application, each PAD is provided with the corresponding UBM layer to ensure that all PADs can be led out based on the corresponding UBM layers without interference with each other. The sinking bottoms of the UBM layers completely cover the corresponding PADs, can protect the PADs from corrosion and have good contact ends for lead-out.

In some preferred implementations, the sinking metal structural bodies sink inwards obliquely.

Specifically, the UBM layers that sink inwards obliquely have sinking grooves that gradually expands upwards, which facilitates production of the electric connection structures in step S4 to connect the bottoms of the UBM layers and conduct with the PADs.

In some preferred implementations, step S4 includes:
S41′, releasing the carrier from the plastic package bodies; and
S42′, inverting the plastic package bodies after the carrier is released, and producing rewiring layers, opening ink windows and mounting balls sequentially.

Specifically, the front sides of the chip monomers in the plastic package bodies after the carrier is released and inverted are arranged upwards, i.e., the structural metal layers surrounded by the plastic package layers are positioned on the top surfaces of the plastic package bodies and exposed. Therefore, the preparation method in the embodiments of this application can obtain the electric connection structures used for leading out the PADs by producing the rewiring layers, opening the ink windows and mounting the balls after the carrier is released.

More specifically, since the chip monomers and the plastic package layers are connected to the carrier based on the temporary bonding layers, the carrier can be quickly released by releasing the temporary bonding layers in step S41′.

In a second aspect, referring to FIG. 6 to FIG. 8, some embodiments of this application further provide a package structure, which is prepared by the preparation method of a chip package structure provided in the first aspect.

In a packaging process of the chip package structure in the embodiments of this application, first the chips on a wafer are used as processing benchmarks to produce the conductive structures, so that the conductive structures can be accurately arranged on the chips and protect the PADs of the chips, and plastic packaging is performed on the chip monomers obtained by dicing and the corresponding conductive structures simultaneously to obtain the plastic package bodies. Therefore, the preparation method of a chip package structure in the embodiments of this application omits the processes of laser drilling and later metal layer covering, eliminates a deviation caused by laser drilling, and improves the processing precision of the package structure, thereby improving the yield of products, simplifying the whole chip packaging process, and effectively improving the packaging efficiency.

### Embodiment 1

As shown in FIG. 6, the package structure is prepared by face-up packaging, and includes:
first plastic package layers 1a;
first chip monomers 2a, arranged in the first plastic package layers 1a;
first balls 3a, arranged on the top surfaces of the first chip monomers 2a and within the first plastic package layers 1a; and
first electric connection structures, arranged on the top surfaces of the first plastic package layers 1a.

More specifically, the top surfaces of the first balls 3a are flush with the top surfaces of the first plastic package layers 1a.

Specifically, the top surfaces of the first balls 3a being flush with the top surfaces of the first plastic package layers 1a is conducive to production of the first electric connection structures, so that the electric connection structures can be accurately connected to the corresponding first balls 3a to lead out corresponding PADs.

More specifically, the first electric connection structures include first rewiring layers 4a, first ink layers 5a and second balls 6a sequentially arranged from bottom to top. The first ink layers 5a is provided with a plurality of ink windows, and the second balls 6a are connected to the first balls 3a through the ink windows and the first rewiring layers 4a.

### Embodiment 2

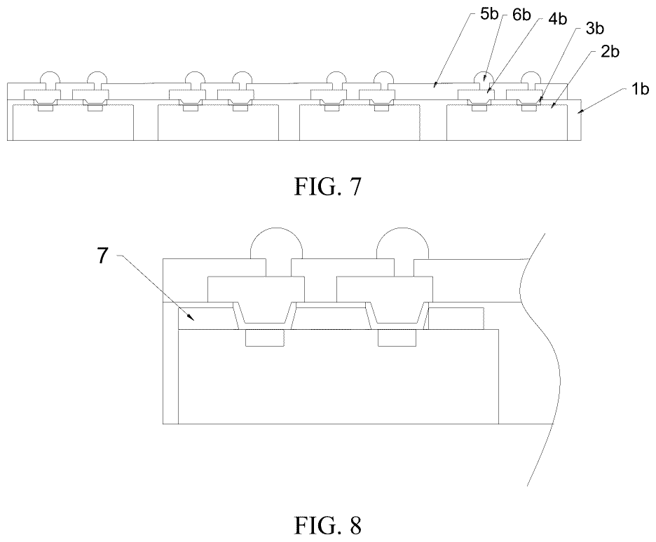

As shown in FIG. 7, the package structure is prepared by face-down packaging, and includes:
second plastic package layers 1b;
second chip monomers 2b, arranged within the second plastic package layers 1b, and provided with structural metal layers 3b on the top surfaces; and
second electric connection structure, arranged on the second plastic package layers 2b and the structural metal layers 3b.

The second electric connection structures include:
second rewiring layers 4b, arranged on the structural metal layers 3b;
second ink layers 5b, arranged on the second rewiring layers 4b and provided with a plurality of ink windows; and
third balls 6b, arranged on the second ink layers 5b and connected to the second rewiring layers 4b through the ink windows.

More specifically, as shown in FIG. 8, the package structure may be further provided with dielectric thickening layers 7 to thicken the edges of the structural metal layers 3b.

Based on the above, the embodiments of this application provide the preparation method of a chip package structure and the package structure, in the preparation method of the package structure, first the chips on the wafer are used as processing benchmarks to produce the conductive structures, so that the conductive structures can be accurately arranged on the chips and protect the PADs of the chips, and plastic packaging is performed on the chip monomers obtained by dicing and the corresponding conductive structures simultaneously to obtain the plastic package bodies. Therefore, the preparation method of a chip package structure in the embodiments of this application omits the processes of laser drilling and later metal layer covering, eliminates a deviation caused by laser drilling, and improves the processing precision of the package structure, thereby improving the yield of products, simplifying the whole chip packaging process, and effectively improving the packaging efficiency.

In the description of this specification, reference terms “one implementation”, “some implementations”, “exemplary implementations”, “examples”, “specific examples”, or “some examples” refer to specific features, structures, materials, or characteristics described in conjunction with the implementations or examples being included in at least one implementation or example of the present disclosure. In this specification, schematic expressions of the above terms do not necessarily refer to the same implementations or examples. Moreover, the specific features, structures, materials, or characteristics described may be combined in an appropriate manner in any one or more implementations or examples.

The descriptions above are just some implementations of the present disclosure. For those skilled in the art, a number of variations and improvements can also be made without departing from the spirit of the present disclosure, and those all fall within the scope of protection of the present disclosure.

What is claimed is:

1. A preparation method of a chip package structure, wherein the method comprises the following steps:
S1, providing a wafer and producing conductive structures on the wafer based on chip distribution;
S2, performing wafer dicing based on the chip distribution to obtain chip monomers;
S3, producing plastic package bodies comprising a plurality of chip monomers based on the chip monomers; and
S4, producing electric connection structures on the plastic package bodies.

2. The preparation method of a chip package structure according to claim 1, wherein the conductive structures are first balls;
step S1 comprises:
S11, providing a wafer and mounting first balls on the wafer based on the chip distribution; and
step S3 comprises:
S31, providing a carrier and fixing the chip monomers onto the carrier;
S32, performing plastic packaging on the first balls to form plastic package layers, the top surfaces of the plastic package layers being higher than or equal to the top ends of the first balls; and
S33, thinning the plastic package layers to make the tops of the first balls have flat exposed ends.

3. The preparation method of a chip package structure according to claim 2, wherein the thinning process is performed to reduce ⅓ to ⅔ of the volume or height of the first balls.

4. The preparation method of a chip package structure according to claim 2, wherein the first balls cover PADs of chips on the wafer.

5. The preparation method of a chip package structure according to claim 2, wherein step S4 comprises:
S41, producing rewiring layers, opening ink windows and mounting second balls sequentially on the tops of the plastic package layers to produce the electric connection structures; and
S42, releasing the carrier to obtain a plastic package body.

6. The preparation method of a chip package structure according to claim 2, wherein in step S31, the bottom surfaces of the chip monomers are fixed onto the top surface of the carrier based on temporary bonding layers.

7. The preparation method of a chip package structure according to claim 2, wherein the method further comprises the following step:
S5, cutting the plastic package body after the electric connection structures are produced to obtain a finished package body.

8. The preparation method of a chip package structure according to claim 2, wherein the method further comprises the following step performed between step S3 and step S4:
covering the flat exposed ends of the first balls with nickel metal layers.

9. The preparation method of a chip package structure according to claim 1, wherein the conductive structures are structural metal layers;
step S1 comprises:
S11′, providing a wafer and arranging structural metal layers on the upper surface of the wafer based on the chip distribution; and
step S3 comprises:
S31′, providing a carrier and fixing the chip monomers face down on the carrier based on temporary bonding layers; and
S32′, performing plastic packaging on the top surface of the carrier to make the top surfaces of plastic package layers higher than or equal to the back sides of the chip monomers to obtain plastic package bodies.

10. The preparation method of a chip package structure according to claim 9, wherein the structural metal layers are under bump metallization (UBM) layers or immersion tin layers.

11. The preparation method of a chip package structure according to claim 10, wherein when the structural metal layers are the UBM layers, the step of arranging the structural metal layers comprises:
S111, defining a passivation pattern on the upper surface of the wafer based on the chip distribution; and
S112, depositing the UBM layers on the upper surface of the wafer according to the passivation pattern.

12. The preparation method of a chip package structure according to claim 11, wherein the step of arranging the structural metal layers comprises the following step performed before step S111:
S110, providing dielectric thickening layers surrounding the PADs on the upper surface of the wafer based on the chip distribution.

13. The preparation method of a chip package structure according to claim 12, wherein the dielectric thickening layers are polyimide (PI) protective layers with a plurality of enclosing pores to surround the respective PADs on the wafer.

14. The preparation method of a chip package structure according to claim 11, wherein the UBM layers comprise sinking metal structural bodies, the number of the sinking metal structural bodies is the same as that of the PADs on the wafer, and the sinking bottoms of the sinking metal structural bodies completely cover the corresponding PADs.

15. The preparation method of a chip package structure according to claim 14, wherein the sinking metal structural bodies sink inwards obliquely.

16. The preparation method of a chip package structure according to claim 9, wherein the structural metal layers cover the PADs of the respective chips on the wafer.

17. The preparation method of a chip package structure according to claim 9, wherein step S4 comprises:
S41′, releasing the carrier from the plastic package bodies; and
S42′, inverting the plastic package bodies after the carrier is released, and producing rewiring layers, opening ink windows and mounting balls sequentially.

18. A package structure, wherein the package structure is prepared by the preparation method of a chip package structure according to claim 1.
